(19) United States
(12) Patent Application Publication
(10) Pub. No.: US 2008/0174331 A1
(43) Pub. Date: Jul. 24, 2008

(54) Structure of test area for a semiconductor tester

(75) Inventors: Lin Yuan-Chi, Hsin-Chu City (TW); Chih-Hung Hsieh, Hsin-Chu City (TW); Shih-Fang Lin, Hsing-Chu City (TW); Hao-Hsin Pan, Hsin-Chu City (TW)

Correspondence Address: SINORICA, LLC, 528 FALLSGROVE DRIVE, ROCKVILLE, MD, 20850, US

(73) Assignee: King Yuan Electronics Co., Ltd.

(21) Appl. No.: 11/819,084

(22) Filed: Jun. 25, 2007

(30) Foreign Application Priority Data
Jan. 19, 2007 (CN) 96102086

(51) Int. Cl. G01R 31/26

(52) U.S. Cl. 324/765

(57) ABSTRACT

Devices and methods for DC and SLT (system level test) integration are disclosed. The DC circuit and the SLT circuit are integrated into the same device. Therefore, the DUT (device under testing) can precede the SLT before the FT (final test) when the DUT passes the DC.

### BACKGROUND OF THE INVENTION

1. Field of the Invention

The present invention relates to semiconductor tester, and more particularly, to devices and methods for DC test and SLT (system level test) integration.

2. Description of the Related Art

The semiconductor test is to check and make sure the function of IC, named Device Under Test/DUT as well, to be complete, and the IC can be binned by the result of test.

However, if the DUT is not fine, it would cause damages to the test circuit. Therefore, DUT is supposed to be performed the DC test first, for example, the open/short circuit test. After ascertaining the DUT as regular, the DUT would be held with the help of the robot of a handler and moved to the SLT circuit test area for the SLT.

FIG. 1 is a schematic diagram illustrating the conventional configuration of a semiconductor tester in a test area. A DUT is held by the robot of a handler and moved from the tray of the input port to the DC test socket 11 of the test area 10 where the DC test is executed. Only the DUT which passes the DC test could be moved to the SLT socket 12 by the robot of the handler for the SLT and would be put on different trays of output port by the SLT result.

Concerning the SLT of the semiconductor tester, the procedure is as followed. First, the programs are written into the Tester. Second, the Test Head sends out the electric signals of the articles of the SLT to the DUT by the Load Board. Then the Test Head would send the result of the SLT to the Handler, and according to the results, the Handler would bin the DUT by its robots.

The DC test, different from the SLT with complex test procedures, is just a simple circuit test to prevent the tester from the damages. Therefore, it spends less time than the SLT and is generally associated with only one robot to transfer the DUT from the DC test to the SLT. However, the back and forth movement may cause time delay and reduce the throughput. The increase on the frequencies of transferring the DUT is in company with the increase of attachment between the DUT and the socket and damages on the DUT to raise the cost.

### SUMMARY OF THE INVENTION

In view of the shortcomings described above in background, the present invention provides a device for DC test and SLT integration which's purpose is to approach the goals that the original devices cannot achieve.

First, the present invention provides a structure of a test area for a semiconductor tester, which includes a plurality of test units and switch elements. Every test unit includes a socket associated with a DC test circuit and a SLT circuit. Every switch element is configured to connect the socket and the circuit board and switches to connect the first circuit or the second circuit according to the information of a tester.

Second, the present invention provides a semiconductor tester, which includes a tester, a handler, an input/output port for DUT and a test area. Wherein the test area further includes a plurality of test units which include a socket, a circuit board having a first circuit and a second circuit and a switch element which connects the socket and the circuit board, and switches to connect the first circuit or the second circuit.

Third, the present invention provides a method for semiconductor tester. It provides at least one test unit and at least one DUT, and couples the DUT with the test unit. After executing the DC test, and checking the result of the DC test and doing decision, it drives a switch element to connect the SLT circuit and executes the SLT. Finally, after recording the result of the SLT, it drives the switch element to connect the DC test circuit.

### BRIEF DESCRIPTION OF THE DRAWINGS

FIG. 1 is a schematic diagram illustrating the conventional configuration of a semiconductor tester in a test area.

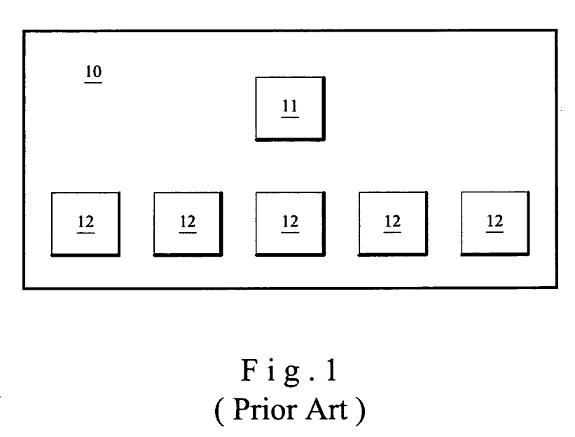

FIG. 2 is the diagram of the structure of the test area according to one embodiment of the present invention.

FIG. 3 is a diagram of the other embodiment of the test area.

FIG. 4 is a flow chart of the test procedure which described by the embodiment of FIG. 3

### DETAILED DESCRIPTION OF THE PREFERRED EMBODIMENT

Devices and methods for DC test and SLT (system level test) integration are disclosed in the present invention; especially, the aperture of the test area is emphasized. For clear and bright, it would be described of the steps and the combinations particularly. It is not limited to perform the present invention only on the special details of the DC test and the SLT. Besides, what is well known to those skilled in the art of the semiconductor tester and methods is not described in detail for preventing the unnecessary limitations. The preferred embodiments of the present invention will be described as follow, but except the preferred embodiments, the present inventions could perform in other embodiments. And the scope of the present invention is not limited by the description; it all by what we claim later.

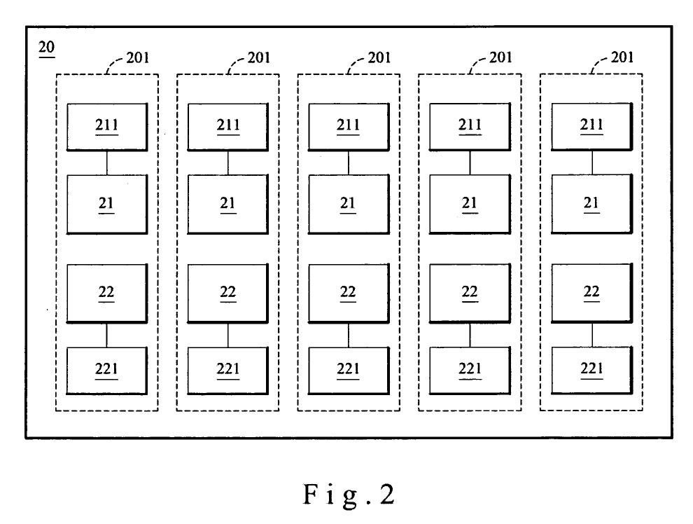

FIG. 2 is a schematic diagram illustrating the structure of the test area according to one embodiment of the present invention. As FIG. 2 shown, the test area 20 includes a plurality of test units 201. Every test unit 201 has a first socket 21, a circuit board 211 corresponding to the first socket 21, a second socket 22 and a circuit board 221 corresponding to the second socket 22. Wherein, the circuit board 211 and the socket board 221 couple with the first socket 21 and the second socket 22 individually.

During the execution of the test of this embodiment, the handler (not shown) moves the DUT into the first socket 21 of the test unit 201 to make the DUT couple with the first socket 21. Then the tester (not shown) would send out messages to drive and execute the DC test, and record the result.

At this moment, if the DUT is disqualified, it is directly binned without execution of subsequent procedure. If the DUT is qualified, the tester would drive the robot on the handler to move the qualified DUT from the first socket 21 to the second socket 22 to make the DUT couple with the second socket 22. Then the tester would send out messages to drive and execute the SLT, and record the result of test. Finally, the tester would drive the robot of the handler to put the DUT on different trays (not shown).

It is noted that the feature of the present invention is to improve the configuration of the test area 20, therefore, details about a conventional semiconductor tester, for examples, the handler, the robot and the tester etc. are not drew. It is obvious, for increasing the throughput of the semiconductor tester, there could be a plurality of robots of the handler to execute the DC test and the SLT; the present invention did not limit it.

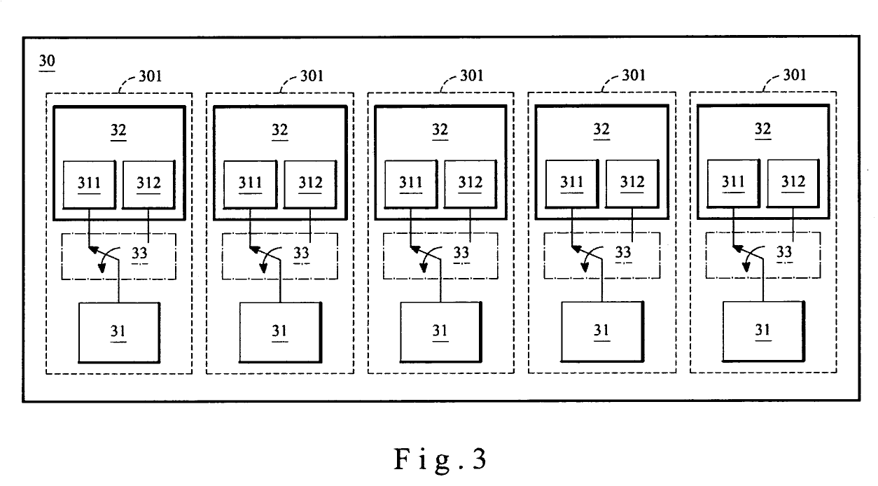

FIG. 2 is a schematic diagram illustrating the structure of the test area according to another one embodiment of the present invention. As shown of FIG. 3, the test area 31 includes a plurality of test units 301, and every test unit 301 has a socket 31 and a circuit board 32 corresponding to the socket 31. The circuit board 32 includes a first circuit 311 (e.g. the DC test circuit) and a second circuit 312 (e.g. the SLT circuit). Meanwhile, there is a switch element 33 between the socket 31 and the circuit boar 32 so that the socket 31 could choose to connect with the first circuit 311 or the second circuit 312 by the switch element 33.

This embodiment describe the procedure of test, wherein the handler (not shown) moves the DUT into the socket 31 of the test unit 301 and make the DUT couple with the socket 31. Then, the tester (not shown) sends out messages to drive the switch element 33 to connect to the first circuit for the DC test which includes the open/close loop testing and record the result of test.

Besides, during driving the switch element 33, alternatively, the electrical connection location on the switch element 33 may be checked first. When the electrical connection location is not correct for the first circuit 311, the switch movement for the electrical connection location may be executed first.

Next, on the condition of the DUT qualified by the DC test, the tester would send out the message to drive the switch element 33 connect to the second circuit 312, execute the SLT and record the result. Otherwise, if the DUT is disqualified, the Tester would record the result and skip over the SLT.

At the end of the test, the Tester would make the handler put the DUT on different trays by the results of the tests, and check if going on the next test of the next DUT or not.

It is obviously, in this embodiment, there is only one robot of the test area 30 to execute both the DC test and the SLT. And it is noted that the feature of the present invention is the structure of the test area 30. Therefore, other details about the conventional semiconductor tester are not illustrated for clarity. Also, for increasing the throughput of the semiconductor tester, there could be a plurality of robots to execute the DC test and the SLT; the present invention did not limit it.

Furthermore, in this embodiment, the switch element 33 may be a switch which is selected from the group consisting of a switch circuit, a duplex, a relay, and a semiconductor device (e.g. a diode). Meanwhile, the switch element 33 may be set alternatively in the circuit board 32 or the socket 31; the present invention did not limit, either.

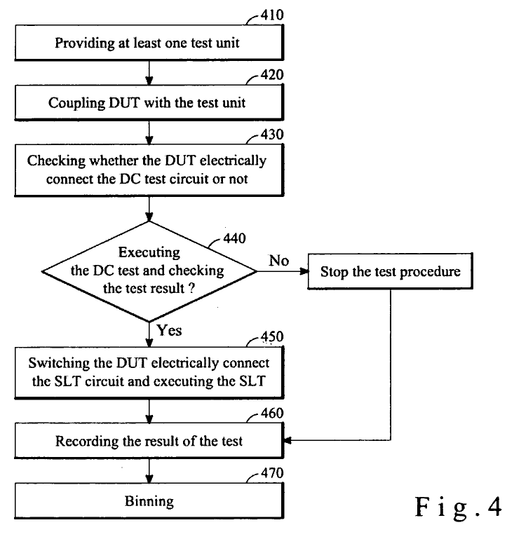

Moreover, please refer to FIG. 4 which is a flow chart of the test procedure which described by the embodiment of FIG. 3.

As FIG. 4 shown, the first step 410 is to provide a test unit 301 associated with a socket 31, a circuit board 32 and a switch element 33 configured for connecting the socket 31. The circuit board 32 includes a first circuit 311 for the DC test and a second circuit 312 for the SLT. At the beginning of the test, the socket 31 is connected the first circuit 311 by the switch element 33.

The step 420 is to couple a DUT with the socket 31 of the test unit 301. The step 430 is to check the electrical connection location of the switch element 33 with the first circuit 311; if the electrical connection location is not correct to connect the first circuit 311, the switch element 33 may switch to confirm that the switch element 33 connects with the first circuit 311.

The step 440 is to execute the DC test, and to check the result of the DC test. When the DUT is disqualified by the DC test, the Tester would stop the procedure of the test and execute step 460 and step 470 which is to record the result and bin.

When the DUT is qualified by the DC test, shown of step 450, the switch element 33 is driven to electrically connect the second circuit 312 and execute the SLT test. And step 460 is to record the result of the test; step 470 is to put the DUT in different trays by the results of tests. After step 470 it is certainly to switch the switch element 33 to connect the first circuit 311 for the DC test.

In the procedure above described, to execute the switch motion and test motion of the switch element 33 is accordance with the messages sent by the Tester. And the Tester would drive the robot to take the DUT on the different trays by the results of tests; check if going on the next test of the next DUT or not.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alternations, improvements and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A structure of test area for a semiconductor tester, wherein the structure of test area comprises at least one test unit and the test unit comprising:
a socket;
a circuit board having a first circuit and a second circuit; and
a switch element executing a switching motion according to a message of the semiconductor tester for making the socket electrically connect the first circuit or the second circuit.

2. A structure of test area for a semiconductor tester according to claim 1, wherein the first circuit is a DC test circuit.

3. A structure of test area for a semiconductor tester according to claim 2, where the second circuit is a SLT circuit.

4. A structure of test area for a semiconductor tester according to claim 1, wherein the first circuit is a SLT circuit.

5. A structure of test area for a semiconductor tester according to claim 4, wherein the second circuit is a DC test circuit.

6. A structure of test area for a semiconductor tester according to claim 1, wherein the switch element is selected from the group consisting of a duplex, a relay, and a semiconductor device.

7. A method for DC test and SLT integration of semiconductor tester, comprising:
providing at least one test unit;
providing at least one DUT (Device Under Test) and coupling the DUT with the test unit;
executing the DC test;
checking the result of the DC test and carrying a decision out;
driving a switch element for making the DUT electrically connect the SLT circuit which is on the test unit;
executing the SLT; and
recording the result of the test and binning the DUT.

8. The method for DC test and SLT integration of semiconductor tester in claim 7, wherein before executing the DC test, checking whether the DUT electrically connect the DC test circuit on the test unit by the switch element or not.

9. The method for DC test and SLT integration in claim 7, wherein when the DUT disqualified by the DC test, a result is directly recorded and the result of the DUT is binned.

10. The method for DC test and SLT integration in claim 7, wherein the DC test comprises opening/short circuit test.

11. The method for DC test and SLT integration in claim 7, wherein the procedure of the test is followed by sequence messages of a tester.

12. The method for test DC and SLT integration in claim 7, wherein the switch element is selected from the group consisting of a duplex, a relay, and a semiconductor device.

13. A semiconductor tester having a tester, a handler, an input/output port of an element under test and a test area, wherein the test area further comprises a plurality of test units, and the test unit comprises:
a socket;
a circuit board having a DC test circuit and a SLT circuit; and
a switch element executing a switching motion by a message of the semiconductor tester for making the socket electrically connect the DC test circuit or the SLT circuit.

14. The semiconductor tester according to claim 13, wherein the switch element is selected from the group consisting of a duplex, a relay, and a semiconductor device.

15. The semiconductor tester according to claim 13, wherein the sorter comprises a plurality of robots.

16. The semiconductor tester according to claim 13, wherein the DC test comprises opening/short circuit test.

17. A semiconductor tester having a tester, a handler, an input/output port of an element under test and a test area, wherein the test area further comprises a plurality of test units, and the test unit comprises:
a first socket;
a DC test circuit electrically connecting the first socket;
a second socket;
a SLT circuit electrically connecting the second socket;
wherein a DUT is sucked by the sorter and then inserted into one of the first socket and the second socket according to the sequence messages of the tester.

18. The semiconductor tester according to claim 17, wherein the handler comprises a plurality of robots.

19. The semiconductor tester according to claim 18, wherein the DC test comprises opening/short circuit test.

20. A structure of test area for a semiconductor tester comprising at least one test unit, wherein the test unit comprises:
a socket;
a circuit board having a DC test circuit and a SLT circuit; and
a switch element executing a switching motion by a message of the semiconductor tester for making the socket electrically connect the DC test circuit or the SLT circuit.

21. The semiconductor tester according to claim 20, wherein the DC test comprises opening/short circuit test.
